(19) United States
(12) Patent Application Publication
(10) Pub. No.: US 2011/0062779 A1
(43) Pub. Date: Mar. 17, 2011

(54) METHOD FOR A KIT FOR GENERATING ELECTRICITY FROM SOLAR PANELS

(76) Inventors: Chris John Reichart, (US); Gerald G. Glass, (US)

(21) Appl. No.: 12/558,964

(22) Filed: Sep. 14, 2009

(51) Int. Cl. B60L 1/00; H01L 31/045; H02J 7/35

(52) U.S. Cl. 307/10.1; 136/245; 320/101

(57) ABSTRACT

A kit for generating electricity from solar power to an electrical system inside any vehicle relying on a photovoltaic panels in the format of a foldable solar panel (1) DC disconnects (2,3); charge controller (4); batteries (5); electrical wires, and fuses.

### CROSS-REFERENCE TO RELATED APPLICATIONS

U.S. Ser. No. 12/426,927

### SEQUENCE LISTING OR PROGRAM

Not Applicable

### BACKGROUND

1. Field

This application relates to solar electricity generated by photovoltaic panels and the application to a solar panel in the format of a foldable solar panel.

2. Prior Art

This method relates to the solar power used to charge batteries specifically designed to provide large amounts of power, but it can scaled down to generate smaller amounts of power. Solar power inventions have been around for a while, but no invention was ever created to be a portable and foldable.

Examples of solar-power generators for vehicles and are described in the following documents:

U.S. Pat. No. 5,725,062, which was issued to Froneck on Mar. 10, 1998 described a vehicle top solar power generator, where the solar panel is mounted on the top of the vehicle.

U.S. Pat. No. 4,602,694, which was issued to Weldin on Jul. 29, 1986, was limited to a detailed combination of a motor, a generator, a traction wheel and other devices.

U.S. Pat. No. 5,148,736 which was issued to Juang on Sep. 22, 1992, described an automatic solar-powered car ventilator.

U.S. Pat. No. 5,680,907, which was issued to Weihe on Oct. 28, 1997, described an auxiliary solar-power automobile drive system which would be an alternative source of power for the primary source of fossil fuel energy. This provided the logic but not a solution to provide enough solar power to an electrical system inside a truck/semi/vehicle or an electrical system for a tractor/truck/semi/vehicle.

U.S. Pat. No. 6,380,481 which was issued to Muller on Apr. 30, 2002, involved solar panels which were used but they were foldable and the system was designed to run with the assistance of kinetic energy.

U.S. Pat. No. 289,573 which was issued to Scott on Dec. 4, 1883 covers the early design of the foldable shade.

U.S. Pat. No. 4,865,106 which was issued to Wichelman on Sep. 12, 1989, covers the foldable shade.

U.S. Pat. No. 5,184,659 which was issued to Hector on Feb. 9, 1993 also covers the windows shade foldable apparatus.

Our method involves a unit that is portable and foldable and is installed on the vehicle dashboard. It is designed to provide a specific service, which is an alternate power source for the operation of an electrical system that would otherwise require the costly operation of the main drive engine while the vehicle/load is parked or while it remains stationary for any significant period of time.

In a 1987 article, McCosh, D. “Racing with the Sun”, Popular Science Magazine, November 1987, McCosh noted that solar energy was a great source of electricity. No additional mention was made about powering the AC units or an electrical system. Back in 1987 McCosh was hoping for a technical breakthrough which would reduce the cost of solar panels, and now 22 years later we have the kit to generate electricity for the purpose of running an electrical system for a truck/semi/vehicle for a fraction of the cost, as sought in 1987.

In his book, Tertzakian, P. “A Thousand Barrels a Second: The Coming Oil Break Point and the Challenges Facing an Energy Dependent World”, McGraw-Hill Professional, 2006, 8,23,79, Tertzakian explained the importance of getting away from the “oil only world” we live in and start to build a portfolio of energy sources. Solar power is mentioned in his book as an important part of such an energy portfolio. This kit fits Tertzakian's description perfectly as we are not replacing the power source of the vehicle, but we are providing an additional power source that will be added to the overall power use and efficiency of the an electrical system inside a truck/semi/vehicle, specifically for an electrical system power usage. If an electrical system is ran with some or all of his power consumption coming from solar energy the overall fuel use by the vehicle will drop, and therefore a saving will start to be realized immediately by the consumer.

Finding a replacement for oil fuels is the main purpose of several books and authors in the recent years. In his book Campbell, C. J. “Oil Crisis,” multi-science publishing, 2005, 303, also brought up the necessity of finding alternative energy sources.

After a review of all the parts of the car that are exposed to direct sun light we have concluded that the window is the best location to place a solar panel, it was a natural evolution to think about a foldable solar panel made of photovoltaic material. Many vehicles, such as an aircraft and mobile homes, have windows that are exposed for many hours to direct sunlight. Our method consists in applying photovoltaic material to the surface of a regular foldable foldable solar panel.

Once the vehicle is parked the owner/operator will be able to unfold the solar panel(s) and connect to the vehicle internal solar grid which will collect and store the electricity generated by the photovoltaic cells.

### SUMMARY

In light of the publicly perceived need for solar energy for transportation vehicles and/or at minimum the supplementation of the power source for an electrical system inside a truck/semi/vehicle, the object of our method is to provide a solar supplemental power source to an electrical system inside a truck/semi/vehicle. This document will describe the construction of a device capable of providing a solar energy power source to operate an electrical system inside a truck/semi/vehicle. This method is powered by solar power and is designed using readily available products. The solar output of this device is up to 816 Watts, 33 Volts and 24.6 Amperes, depending on the number of solar panels connected to the internal solar grid of the vehicle. The system can be configured for different levels of desired power, current and/or voltages. Backup power is provided through the use of batteries. The batteries used for this project are approximately 12 Volts, 290 amperes per hour, but can be configured to meet the 24 Volts at 870 amperes per hour. Power from the solar power system and battery backup is regulated by means of a “charge controller.” This device provides optimal power usage from the panels while regulating the amount of charge going to the batteries and an electrical system inside a truck/semi/vehicle. The Direct Current (DC) disconnect in this system provides an extra layer of safety and facilitate efficient interconnection of the unit with the electrical system inside a truck/semi/vehicle/RV/Bus.

All of the energy generated by the solar panels is stored in batteries which have the following characteristics:
Completely sealed valve regulated;
Flame arresting pressure regulated safety sealing valves;
Operating pressure management and protection against atmospheric contamination;
Computer-aided 99.994% pure heavy-duty lead calcium grid designs;
Tank formed plates, which guarantees evenly formed and capacity matched plates;
Anchored plate groups, to guard against vibration;
Double insulating micro porous glass fiber separators;
Measured and immobilized electrolyte, for a wide range of operating temperatures, and low self discharge rates;
High impact reinforced strength copolymer polypropylene cases with flat top designed covers that are rugged and vibration resistant;
Thermally welded case to cover bonds that eliminate leakage;
Copper and stainless steel alloy terminals and hardware;
Multi-terminal options;
Terminal protectors;
Removable carry handles; and
Classified as “NON-SPILLABLE BATTERY” Not restricted for Air (IATA/ICAO) Provision 67, Surface (DOT-CFR-HMR49) or Water (Classified as non-hazardous per IMDG amendment 27) transportation, compatible with sensitive electronic equipment, Quality Assurance processes with ISO (4400/992579), QS and TUV Certification EMC tested, CE, ETTS Germany (G4M19906-9202-E-16), Tellcordia and Bellcore compliant, UL recognized and approved components (MH29050).

The method utilizes electrical connections with heavy duty cables with a zinc die-cast plug housing. Which is reinforced for durability, good recoil memory, chemical resistance and abrasion resistance. A temperature rating of −90° F. to 125° F. (−68° C. to 52° C.), unbreakable PERMAPLUGS™ featuring Dupont® patented material, which meets SAE J560. Large finger grips for coupling/uncoupling, even with gloves on. Extended plug interior for easy maintenance, protected with anti-corrosive non-conductive, dielectric lithium grease. All cable assemblies are rated for 12 volt systems. All electrical wires connect with the STA-DRY® Wire Insertion Socket, 7-Way #16-720D, with split brass pins along with Anti-Corrosive Dupont Super-Tuff Nylon® housing & lid and stainless steel hinge pin & spring, with inner cavity sealed to prevent contaminants from passing to the wire harness. Extended front barrels for additional cable support, slanted 5° for moisture drain, and elongated holes for mounting adaptability.

All electricity is generated by photovoltaic laminate solar panels. Each solar panel has the following characteristics: rated power (Pmax) 136 Watts, production tolerance +/−5%;, by-pass Diodes connected across every solar cell to protect the solar cell from power loss in case of partial shading or damage of individual solar cells while other cells are exposed to full sunlight.

The adhesive to secure the unit to the vehicle's roof is an ethylene propylene copolymer adhesive-sealant, with microbial inhibitor, high temperature and low light performance. The adhesive is flexible and lightweight, weighting approximately one pound per square foot, compared to five pounds per square foot for standard adhesives. The unit is adhered directly to the roof without penetrations or perforations which is approved by state revenue departments for tax incentives and rebates.

The logical center for this method is a charge controller. The charge controller we selected has the following characteristics: PWM series battery charging (not shunt); 3-position battery select (gel, sealed or flooded); very accurate control and measurement jumper to eliminate telecom noise; parallel for up to 300 Amperes temperature compensation; tropicalization: conformal coating, stainless-steel fasteners & anodized aluminum heat sink, no switching or measurement in the grounded leg, 100% solid state, very low voltage drops, current compensated low voltage disconnect, leds for battery status and faults indication, capable of 25% overloads, remote battery voltage sense terminals. The charge controller has the following electronic protections: short-circuit for solar and load, overload for solar and load, reverse polarity, reverse current at night, high voltage disconnect, high temperature disconnect, lightning and transient surge protection, loads protected from voltage spikes, automatic recovery with all protections.

This kit is designed to provide for approximately 34 hours of operation, with a requirement of approximately 4 hours of sunlight for a full charge. The photovoltaic panels used in this kit are amorphous silicon. By the properties of its construction the panels are capable of using different spectrums of light in which to operate and allow for a broader range of usable sunlight.

Our method generates up to 816 Watts, which is sufficient to provide power to an electrical system inside a truck/semi/vehicle/airplane/RV. The surplus provides enough power for the charge controller to maintain the necessary charge on the battery to extend battery life. Our method operates for up to 34 hours with no sunlight, when deployed in full configuration, when used in the foldable solar panel foldable format the total operation time will be smaller.

### DRAWINGS—FIGURES

The method for generating electricity from solar panels to run an electrical system is described by the appended claims in relation to the description of a preferred embodiment with reference to the following drawings which are described briefly as follows:

FIG. 1 is the electrical diagram of the method;

FIG. 2 is a partially cutaway top view;

FIG. 3 shows the method in place in the format of foldable solar panel from the outside;

FIG. 4 shows the method in place in format of a foldable solar panel from the inside;

FIG. 5 shows another embodiment of the method where the solar panel is embedded in the car dashboard. Not using the foldable solar panel format at all.

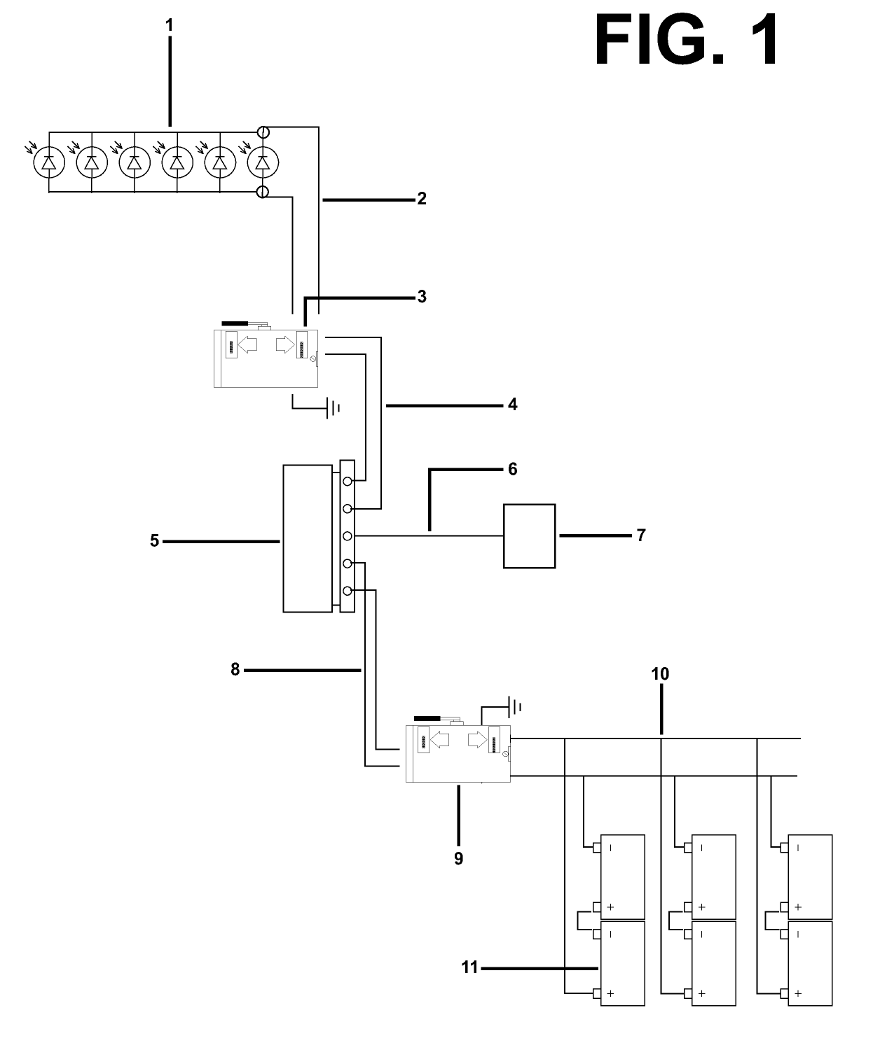

### DETAILED DESCRIPTION—FIGS. 1, 2, 3 AND 4—FIRST EMBODIMENT

Reference is made first to FIG. 1. Photovoltaic (PV) panels 1 that receives solar energy. The electricity generated by the PV panels 1 is transmitted via a wire 2, to a DC Disconnect 3 (DCD). If the DCD circuit 3 is closed, the electricity generated by the PV panels 1 is transmitted via a wire 4 to a charge controller 5. The charge controller 5 is designed to direct the electrical current from the PV panels 1 to a primary load 7 in this embodiment an electrical system inside a truck/semi/vehicle 7 via a wire 6. If the primary load 7 is not receiving the electricity generated by the PV panels 1 the charge controller 5 sends the electricity via a wire 8 to a second DC Disconnect (DCD) 9. If the DCD 9 is closed, the electricity sent by the charge controller 5 is transmitted via a wire 10, to the batteries 11. The batteries 11 store the electricity generated by the PV panels 1. When there is no electricity generated by the PV panels 1 the charge controller 5 allows the electricity stored in the batteries 11 to be transmitted via wire 10, then via DCD 9 and wire 8, to the primary load 7. The charge controller 5 has the capability to be programmed to understand what are the circuit's electrical current needs. This is based on the program set in the charger controller 5 memory. The unit will be able to make logical decisions (based on the charger programmed data). If the load 7 needs power, the charge controller 5 sends electrical power to the load. If the batteries 11 are low in charge, the charge controller 5 sends power to the batteries 11.

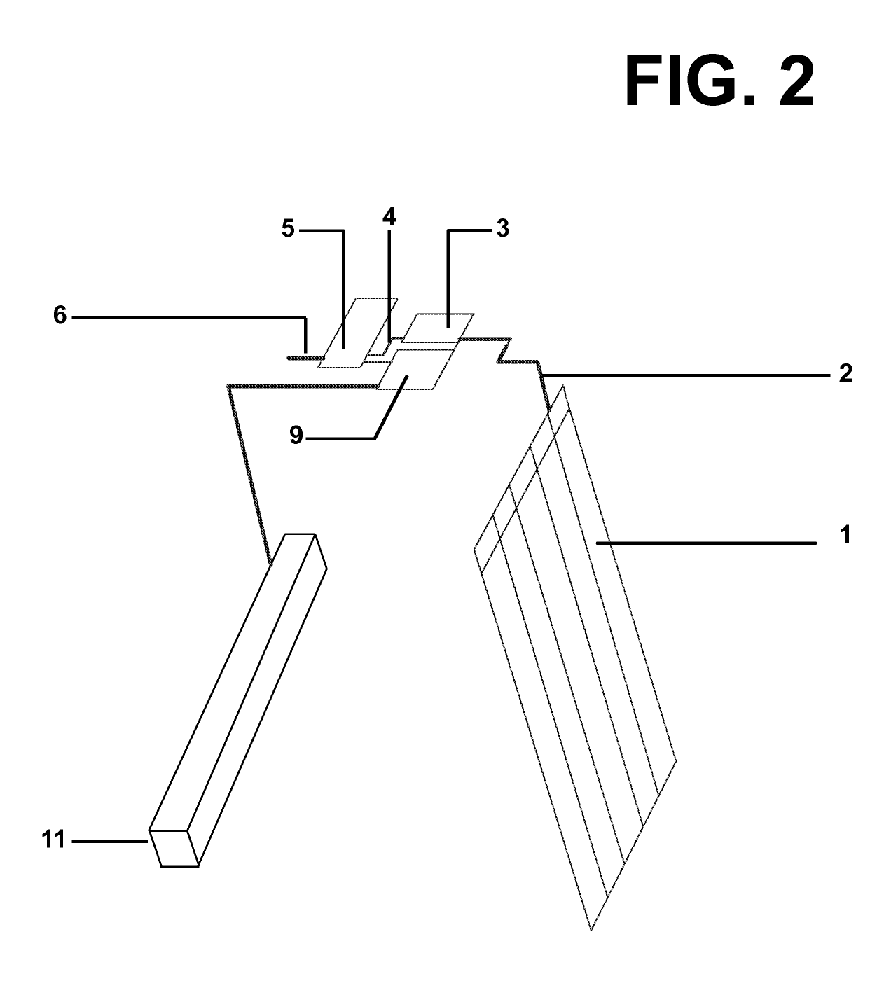

As shown in FIG. 2, the batteries 11 will be assembled and installed inside the truck/semi/vehicle/RV cargo space. The PV panels 1 will be assembled and installed in the format of a foldable solar panel. The wire 2 makes an approximately 900 bend and comes down where it is going to be connected with the DCD 3, which is assembled and installed in the vehicle dashboard. From the DCD 3, the wire 4 brings the electricity generated by the PV panels 1 to the charge controller 5 which is also mounted inside the dashboard. The DCD 9 is also assembled inside the dashboard. Safety is of great concern of this invention. As such, both DC Disconnects 3 and 9 are installed in this kit to provide an extra layer of safety and to facilitate an efficient interconnection of methods for generating electricity from solar panels. The truck/semi/vehicle operator can safely reach the controls for the DCD 3 or the DCD 4 which are placed on the dashboard, and disconnect the PV panels 1 for any necessary service, without risk of getting an electric shock, since the PV panels 1 are always generating electricity when exposed to light. The same principle is applied to the DC disconnect 9 if service needs to be performed to the batteries 11, the truck/semi/vehicle operator can safely close the switch in the DCD 9 and work on the batteries without the risk of an electrical shock.

This method was conceived to work as two separate systems with one point of interconnection being the charge controller 5. The first system will be comprised of the PV panels 1, the DCD 3 and the charge controller 5. The second system will be comprised by the batteries 11, the DCD 9 and the charge controller 5.

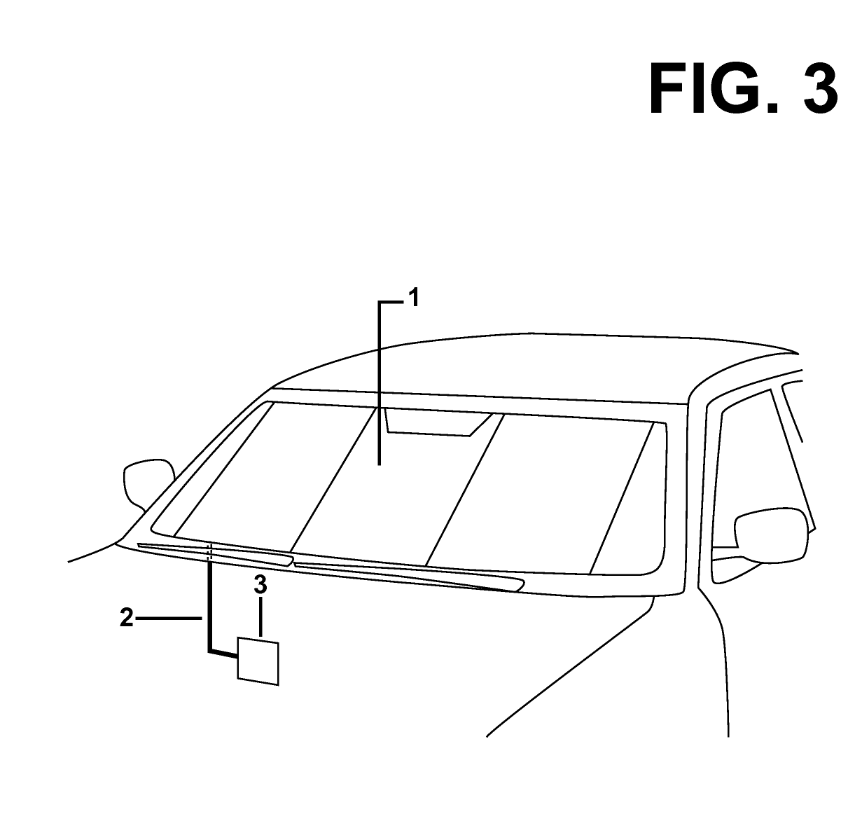

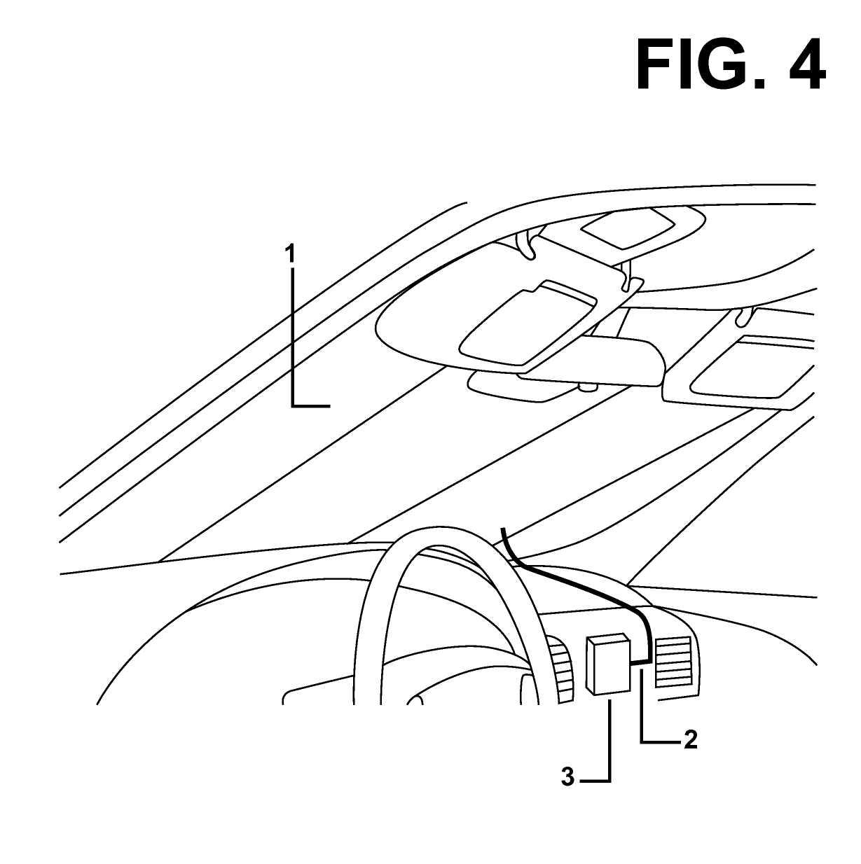

Reference is made to FIG. 3. Where we can see a vehicle with the method in the format of a foldable solar panel with the photovoltaic (PV) panels in place 1. One of the characteristics of this second embodiment is that the PV 1 is foldable and can be stored inside the car when not in use. When in place the PV 1 connects via wire 2 to a DC Disconnect 3 (DCD). From the DCD 3 the method can be used to generate electricity to any device. In FIG. 4 we can see the PV 1 from the inside of the vehicle with the connection via wire 2 to the DCD 3.

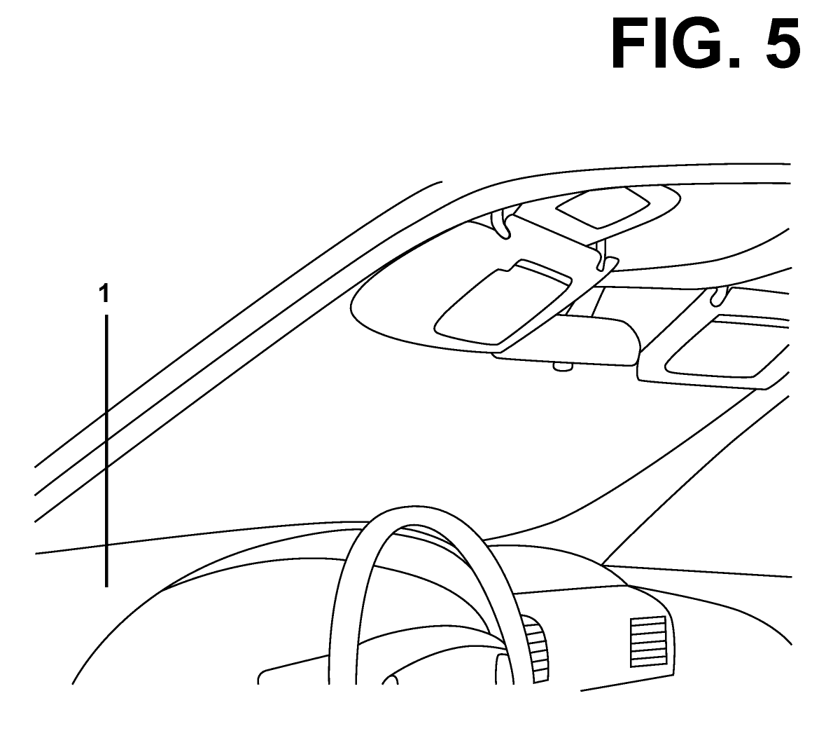

### DETAILED DESCRIPTION—FIG. 5—SECOND EMBODIMENT

Reference is made to FIG. 5 where the method is embedded inside the vehicle dashboard and the PV 1, is visible from behind the steering wheel and the wire 2 and the DCD 3 are also inside the vehicle dashboard.

After our method is completed and attached to the electrical system inside a truck/semi/vehicle/RV. Our method will generate enough power to provide the electrical system inside a truck/semi/vehicle/RV, which could be an AC handling unit, telephone charger, IPOD, DVD Player.

Although the foregoing invention has been described in some detail by way of illustration and example, for purposes of clarity and understanding, it is obvious that certain changes and modifications may be practiced within the scope of the appended claims.

We claim:

1. A method for providing solar power to an electrical system inside a vehicle comprising:
a) one or more photovoltaic panels assembly in the format of foldable solar panel;
b) two or more DC disconnect units that protect against charge overflow;
c) a charge controller that checks a battery's power level, load consumption and amount of electricity generated by the photovoltaic panels;
d) one or more batteries that will store the electricity generated by the photovoltaic panels;
e) an electrical system inside a vehicle that uses the stored energy from the photovoltaic panels.

2. The method as in claim 1 and further comprising:
a) an assembly receptacle that stores the DC disconnect and the charge controller;
b) an electrical connection that connects the photovoltaic panels to the first DC controller.

3. The method as in claim 1 and further comprising:
a) an electrical connection between the first DC disconnect and the charge controller;
b) an electrical connection between the charge controller and the load.

4. The method as in claim 1 and further comprising:
a) an electrical connection between the second DC disconnect and the batteries, for solar power storage;
b) an electrical connection between the batteries and the photovoltaic panel.

5. The method as in claim 1 and further comprising:
a) the logical settings in the DC disconnect to measure the level of electricity needed by the load.

6. The method as in claim 1 and further comprising:
a) the logical settings in the DC disconnect to measure the level of electricity needed by the batteries.

7. The method as in claim 1 and further comprising:
a) the logical settings in the DC disconnect to measure the level of electricity generated by the photovoltaic panels.

8. An improved method for directing the electricity generated by photovoltaic panels into a load.

9. The improved method as in claim 8 and further comprising:
a) in one embodiment the load is an AC handling unit;
b) the manner in which the panels were mounted;
c) the way the wires were run and the manner of installation of the DC disconnect units were wired together make this unit work with enough electrical output to run an AC handling unit.

10. The improved kit as in claim 8 and further comprising:
a) A load that will utilize the electricity generated by the solar panels;

11. The improved kit as in claim 8 and further comprising:
a) the logical settings in the DC disconnect to measure the level of electricity needed by the load.

12. The kit as in claim 8 and further comprising:
a) the logical settings in the DC disconnect to measure the level of electricity needed by the batteries.

13. The kit as in claim 8 and further comprising:
a) the logical settings in the DC disconnect to measure the level of electricity generated by the photovoltaic panels.

14. An improved photovoltaic apparatus for generating and directing the electricity generated by photovoltaic panels into a load. Such apparatus having an extremely high amount of electrical current, is an improvement to all previous apparatus because it is capable of running an AC handling unit or an electrical system inside a truck/semi/vehicle for longer periods of time.

15. An improved and foldable apparatus, in the format of a foldable foldable solar panel that is stored when not in use.

16. The improved and foldable apparatus, in the format of a windows shade as in claim 15 and further comprising:
a) the electrical connection used to connect the PV to the DCD;
b) one or more photovoltaic panels assembly in the format of foldable solar panel;
c) two or more DC disconnect units that protect against charge overflow;
d) a charge controller that checks a battery's power level, load consumption and amount of electricity generated by the photovoltaic panels;
e) one or more batteries that will store the electricity generated by the photovoltaic panels;
f) an electrical system inside a vehicle that uses the stored energy from the photovoltaic panels.
